(19) United States
(12) Patent Application Publication
(10) Pub. No.: US 2007/0081379 A1
(43) Pub. Date: Apr. 12, 2007

(54) Write assist for latch and memory circuits

(75) Inventors: Michael Patrick Clinton, Allen, TX (US); Stephen Keith Heinrich-Barna, Murphy, TX (US); Theodore W. Houston, Richardson, TX (US); George B. Jamison, Murphy, TX (US); Kun-hsi Li, Plano, TX (US); Jonathon Barry Miller, Dallas, TX (US); Bryan David Sheffield, McKinney, TX (US)

Correspondence Address: TEXAS INSTRUMENTS INCORPORATED, P O BOX 655474, M/S 3999, DALLAS, TX, 75265, US

(73) Assignee: Texas Instruments, Inc.

(21) Appl. No.: 11/234,346

(22) Filed: Sep. 23, 2005

(51) Int. Cl. G11C 11/24

(52) U.S. Cl. 365/149

(57) ABSTRACT

One embodiment provides a system to assist setting a state of a latch system. The system includes a latch system connected to a node, the latch system residing in one of a first state and a second state. A charge storage device is coupled to maintain the node at a first voltage according to an amount of stored charge. A write assist system is connected between the node and a second voltage. The write assist network is configured, when the node is selected, to discharge the charge storage device and to pull the node from the first voltage to a discharge voltage that is outside a range defined by the first voltage and the second voltage to facilitate setting the latch system to another of the first state and the second state.

### TECHNICAL FIELD

This invention relates to electronic circuits, and more specifically to a system to facilitate writing to latch circuits, such as are utilized in certain types of memory.

### BACKGROUND

Integrated circuits (ICs) are widely used in many applications. There is a continuing demand for semiconductor memory devices with higher density and low power consumption. Semiconductor memory devices include, for example, SRAM (static random access memory) and DRAM (dynamic RAM) devices. Although DRAM may provide a high degree of integration, SRAM is typically preferred over DRAM for many applications because SRAM cells can operate at higher speeds and lower power dissipation than DRAM cells. For example, SRAM cells typically do not require refreshing and can store data indefinitely as long as such cells are powered. In contrast, DRAM cells must be periodically refreshed.

One well-known conventional structure of an SRAM cell is a 6T (six transistor) cell that comprises six metal oxide semiconductor (MOS) transistors. Briefly, a 6T SRAM cell comprises two cross-coupled inverters that form a latch circuit. The latch is connected between high and low voltage rails, such as power and ground, and is connected to a pair of access transistors. Each inverter comprises two transistors (typically an NMOS pull-down transistor and pull-up PMOS transistor). The latch, which is formed by the first and second cross-coupled inverters, is connected between two storage nodes. One of the storage nodes is pulled low and the other storage node is pulled high. Each storage node is connected to a bit line or complementary bit line of a bit line pair via an access transistor. The gate terminals of the access transistors are commonly connected to a wordline. When the access transistors are deactivated, the storage nodes are essentially insulated from the bit lines, although some leakage may occur.

As voltage supplies continue to scale, it is becoming increasingly difficult to ensure a stable bit cell that can also be easily written to.

### SUMMARY

The present invention relates to electronic circuits, and more particularly to systems that facilitate writing to latch circuits, such as are utilized in certain types of memory (e.g., static random access memory (SRAM).

One embodiment provides a system to assist setting a state of a latch system. The system includes a latch system connected to a node, the latch system residing in one of a first state and a second state. A charge storage device is coupled to maintain the node at a first voltage according to an amount of stored charge. A write assist network is connected between the node and a second voltage. The write assist network is configured, when the node is selected, to discharge the charge storage device and to pull the node from the first voltage to a discharge voltage that is outside a range defined by the first voltage and the second voltage to facilitate setting the latch system to another of the first state and the second state.

Another embodiment of the present invention provides a memory system, having a high voltage rail and a low voltage rail for supplying power to the memory system. The memory system includes at least one memory cell connected with at least one bitline, the at least one memory cell storing a value according to at least two states of the memory cell. A write driver is connected to drive the voltage of the at least one bitline to a discharge voltage that resides outside of the high and low voltage rails to facilitate changing the at least one memory cell from a first state to another of the at least two states. For example, the bitline can be driven to a voltage that is below the low voltage rail.

Yet another aspect of the present invention provides a system to facilitate writing to a memory cell. The system includes means for electrically connecting a selected bitline to a discharge node, the memory cell being connected with the selected bit line. The system also includes means for electrically connecting the discharge node with a low voltage rail, such that the selected bitline discharges toward the low voltage rail. The system also includes means for pulling the discharge node, while the discharge node is electrically connected to the selected bitline, to a discharge voltage that is less than the voltage of the low voltage rail to facilitate changing a state of the memory cell.

### BRIEF DESCRIPTION OF THE DRAWINGS

FIG. 1 illustrates an example of a write assist system that can be implemented in accordance with an aspect of the invention.

FIG. 2 illustrates another example of a write assist system that can be implemented in accordance with an aspect of the invention.

FIG. 3 illustrates yet another example of a write assist system that can be implemented in accordance with an aspect of the invention.

FIG. 4 illustrates still another example of a write assist system in accordance with an aspect of the invention.

FIG. 5 illustrates an example of a programmable write assist system that can be implemented in accordance with an aspect of the invention.

FIG. 6 illustrates another example of a programmable write assist system that can be implemented in accordance with an aspect of the invention.

### DETAILED DESCRIPTION

Some types of memory, including static random access memory (SRAM), and other circuits employ latches to maintain the state of a memory (or bit) cell. For example, during a write operation of an SRAM cell, a write driver is activated to discharge a selected the bitline (BL). As a result of discharging the BL, the data in an associated bit cell, which includes latch circuitry, is flipped to a different state. As supply voltages (V_{DD}) for memory circuits continue to scale lower, such as below about 1 V, it becomes increasingly difficult to ensure proper write operation for bit cells. Accordingly, the present invention provides an approach that enables a selected bit line to be discharged below a low voltage rail, such as electrical ground, referred to herein as V_{SS}. In one example, the present invention includes a write driver that is operative to drive the voltage of the bitline to a voltage that resides outside of the rail voltages (e.g., outside V_{DD} and V_{SS}) to facilitate changing the state of the memory cell to state.

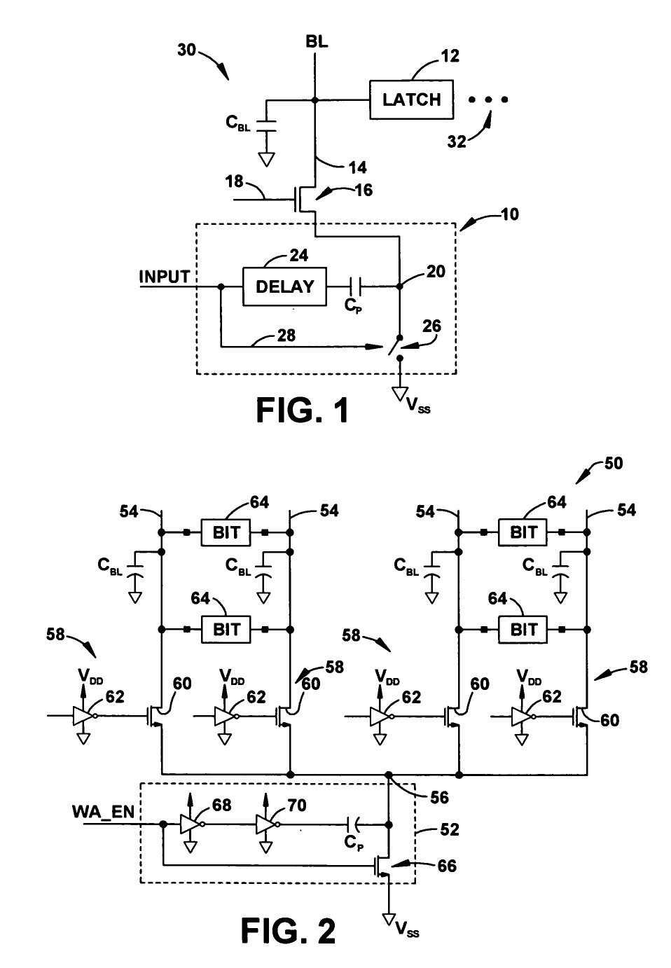

FIG. 1 depicts an example of a write assist system 10 that can be utilized to facilitate setting a state of an associated latch system 12 . The latch system 12 can reside in one of two or more states, such as to define a value of a memory cell (e.g., a bit cell). In this regard, the latch 12 is connected to a node 14, such as through an access transistor (not shown). In the context of a memory circuit, the node 14 can correspond to a bitline (BL). The write assist system 10 is connected between the node 14 and V_{SS}. For example, the write assist system 10 can be implemented as part of a write driver that includes a transistor device 16, such as a metal oxide semiconductor (MOS) device. A bitline capacitor CBL is connected between the node 14 and a low voltage rail, indicated at V_{SS}, such as electrical ground. The C_{BL} is configured to maintain the node 14 at a desired substantially fixed voltage level according to charge stored in C_{BL}, such as corresponding to a positive supply rail (V_{DD}).

The transistor device 16 can be activated between an electrically conductive and non-conductive state according to a control input (e.g., a write enable) signal provided at 18 corresponding to the gate of the transistor device 16. The write assist system 10 is connected between the transistor device 16 and the low voltage rail V_{SS}. The transistor device 16 provides means for electrically connecting the node 14 with the discharge node 20. Thus, by activating the transistor device 16 to a conductive state, the node 14 is connected to the discharge node 20 of the write assist system 10.

The write assist system 10 is configured pull the selected node (e.g., a selected bitline) to a voltage that is below V_{SS} (e.g., a negative voltage). For example, the write assist system 10 electrically couples the discharge node 20 to the low voltage rail V_{SS} based on an INPUT signal. The write assist system 10 is connected between the node 14 and V_{SS}, such as through the transistor device 16. For the context of a memory circuit, such as SRAM, the INPUT signal can correspond to a write assist enable timing signal that is asserted by associated control circuitry (not shown) to implement a write operation. Thus, when the node 14 is selected by the control input provided at 18 and when the INPUT signal to the write assist system 10 enables the write assist system 10, the node 14 is connected to the discharge node 20 which is also connected to V_{SS}. Since C_{BL} initially maintains the node 14 precharged to about the positive voltage rail V_{DD}, when the switch device 16 is activated to a conductive state and when the write assist circuit couples the discharge node 20 to V_{SS}, the node 14 is discharged towards V_{SS}. The write assist system 10 is configured to pull the discharge node 20 and the selected node 14 to a voltage that is below V_{SS} (e.g., a negative voltage), such that the state of the latch system 12 can be changed in a more stable manner.

Turning to the contents of the write assist system 10, the write assist system includes a delay network 24 connected in series with a capacitor C_{P} between the INPUT and the discharge node 20. A switch (e.g., a transistor) device 26 is connected between the discharge node 20 and V_{SS}. In the example of FIG. 1, the state of the switch device 26 varies between a conductive and a non-conductive state in response to the INPUT signal, as indicated schematically at 28. The switch device 26 further provides means for electrically connecting the discharge node 20 with V_{SS}, such that the node 14 discharges toward V_{SS}. It is to be understood that, alternatively, the delay network 24 could provide a delayed version of the INPUT signal for controlling the switch device 26. Those skilled in the art will understand and appreciate other circuitry that can be utilized to implement the write assist system 10 for pulling the selected node 14 (e.g., a bitline of a memory circuit) to a negative voltage according to an aspect of the present invention.

By way of further example, the INPUT signal can be applied to maintain the switch device 26 in a closed condition to electrically connect the discharge node 20 with V_{SS}. Appropriate controls (not shown) can change the state of the INPUT signal to deactivate the switch device 26 to an open condition during a write event. For instance, while the transistor device 16 is activated to a conductive state during a write event, the switch device 26 is initially closed. Accordingly, the bitline capacitor C_{BL} discharges through the transistor device 16 and through the switch device 26 toward V_{SS}. When the INPUT signal deactivates the switch device 26 (i.e., the switch device opens) to electrically isolate the discharge node 20 from V_{SS}, the INPUT signal is delayed through the delay network 24 and is applied to discharge C_{P}. The delay network 24 is configured to set the delay from when the switch device 26 is opened until the charge is pulled from C_{P}. The amount of delay can be variable or fixed, such as from zero (or no delay) to some predetermined maximum. The delay network 24 thus helps prevent coupling charge from C_{P} from being pulled to V_{SS}. After implementing the appropriate delay on the INPUT signal, the capacitor C_{P} discharges, pulling the discharge node 20 to a corresponding voltage that is less than V_{SS}. Since the discharge node 20 is pulled below V_{SS}, the bitline node 14 is also pulled to the low voltage below V_{SS} (less any voltage drops across the switch devices 16 and 26). By pulling the node 14 below V_{SS}, the stored state in the latch system 12 can be changed in a more stable manner.

The negative voltage at the discharge node 20 during a write operation can be set as a function of the capacitances C_{BL} and C_{P}. The approach shown and described with respect to FIG. 1 is particularly useful as the voltage supplies continue to scale down such as where the voltage supply is less than one volt. Those skilled in the art will understand and appreciate that the latch system 12 can be implemented as any type of latch structure, including those implemented in SRAM. Such an SRAM structure, for example, can implement the latch network 12 as part of a single port or multi-port memory cell. In such circuits, the write assist system 10 can be utilized to drive a bitline (corresponding to node 14) below electrical ground to facilitate writing and changing the state of the respective memory cells.

Additionally or alternatively, those skilled in the art will understand and appreciate that the write assist system 10 can be implemented in an integrated memory circuit 30. having a plurality of latch systems (corresponding to respective memory cells, as indicated by the ellipsis 32. The integrated circuit 30 further can be configured with control circuitry to selectively enable or disable the write assist system 10. For example, the write assist system 10 can be enabled depending upon performance requirements, identified process variations as well as based on the threshold voltages of the transistors implemented in the latch system 12. For example, the effects of process variations on the proportionality of the respective capacitors C_{BL} and C_{P} can also be measured (e.g., by margin testing) so that a suitable negative voltage at the discharge node 20 can be designed into the integrated memory circuit 30 implementing the write assist system 10. As another example, the capacitor C_{P} can be a variable capacitance, such as implemented as a network of capacitors, which can be selectively swapped in and out of the write assist system 10 to set the capacitance C_{P}.

Additionally, while the write assist system 10 (as well as other examples shown and described herein) is described as including a delay network 24 and capacitor C_{P}, such components are not required according to an aspect of the present invention. For example, the switch device 26 can be implemented as a metal oxide semiconductor (MOS) transistor device having an inherent (or parasitic) gate-to-drain capacitance. This inherent gate-to-drain capacitance can be utilized in place of the separate capacitance provided by C_{P}. The delay may also be set to zero or eliminated from the write assist system according to an aspect of the present invention. Other variations and permutations will be apparent based on the other examples provided herein.

FIG. 2 depicts an example of part of a memory system (e.g., an integrated memory circuit) 50 implementing a write assist system 52 according to an aspect of the present invention. The memory system 50 includes a plurality of bitlines 54 that are connected to a corresponding discharge node 56 through a respective write driver 58. In the example of FIG. 2, each write driver 58 includes an inverter 62 coupled to drive a gate of an n-channel metal oxide semiconductor (NMOS) transistor device 60. The write assist system 52 can be implemented as part of the write driver 58. Those skilled in the art will understand that the inverters 62 are not required to implement the respective drivers 58. Each write driver 58 provides means for electrically connecting a respective bitline 54 with the discharge node 56, such as based on a write enable input signal. The NMOS device 60 is connected between the bitline 54 and the discharge node 56. A bit cell (or wordline device) 64 is electrically connected between a pair of respective bitlines 54. The bit cells 64, for example, correspond to rows of a memory array with each respective bitline 54 corresponding to a respective column of the memory. As an example, each bit cell 64 includes a latch system connected between a pair of access transistors that are controlled by a wordline to selectively couple or isolate the latch systems to respective bitlines 54. While a pair of bit cells 64 is depicted as being connected between a respective pair of bitlines 54, it is to be understood and appreciated that any number of respective cells can be implemented in a memory system 50. For instance, the write assist system 52 can be utilized in single port as well as multi-port memory systems.

One or more bitline capacitors, indicated at C_{BL}, are electrically connected between each of the respective bitlines 54 and V_{SS}. A given bitline 54 is selected based on a selection signal provided to the respective write driver 58. In particular, the selection signal can be provided by a column decoder to a given input of an inverter 62 of the write driver 58 to select a corresponding bitline 54. In the example of FIG. 2, each inverter 62 is connected between the respective voltage rails V_{DD} and V_{SS} to set the voltage at the respective outputs as either V_{DD} or V_{SS} based on the selection signal.

The write assist system 52 is electrically coupled between the discharge node 56 and V_{SS}. The write assist system 52 is configured to pull the discharge node 56 to a voltage that is less than V_{SS}, namely a negative voltage V_{NEG}, during a write operation. For example, the write assist system 52 is activated in response to a write assist enable (WA_EN) signal, such as corresponding to a timing signal that gets asserted (de-asserted) during a write operation when a given bit cell 64 in the memory system 50 is being written to. Thus, when a given write driver 58 is activated to a conductive state, the bitline 54 is electrically connected with the discharge node 56 through the NMOS device 60, which bit line 54 is initially pulled to V_{SS} by activation of a corresponding transistor device 66 in the write assist system 52. The transistor 66 is connected between the discharge node 56 and V_{SS}. The transistor device 66 can operate as a switch having one of two states depending on the WA_EN signal. As one example, the WA_EN signal can be a normally high signal that activates the transistor 66 to an on condition to electrically connect the discharge node 56 with V_{SS}. During the initial phase of the write process, the selected bitline 54 thus is discharged toward V_{SS} (e.g., zero volts) through the transistor 66.

The write assist system 52 also includes a delay network formed of a pair of inverters 68 and 70 that are electrically connected in series between the WA_EN input and a write assist capacitor C_{P}. The write assist capacitor C_{P} is electrically connected between the inverter 70 and the discharge node 56. In the example of FIG. 2, the discharge transistor 66 is controlled in response to the WA_EN signal that is provided with selection of a given bitline 54 through activation of the associated write driver 58. For instance, the WA_EN signal can be asserted (e.g., at its normal high voltage level) during a first part of a write operation. This results in the bitline capacitor C_{BL} discharging the bitline 54 toward V_{SS} through the write driver 58 and through the discharge transistor 66 during a first portion of the write operation. After the bitline 54 has been discharged to about V_{SS}, the WA_EN signal can be changed (e.g., to a low voltage level) to turn off the discharge transistor 66.

The write assist system 52 is configured to pull the discharge node 56 to a voltage that is below V_{SS} during a second portion of the write operation. By way of example, after the delay implemented by the inverters 68 and 70, the write assist capacitor C_{P} discharges to pull the discharge node 56 to a voltage that is below V_{SS}, namely V_{NEG}. The amount of delay can vary (e.g., from zero to a predetermined delay value) based on the configuration of the inverters 68 and 70. The negative voltage V_{NEG} produced during the write operation by the circuit arrangement of FIG. 2 varies as a function of the positive supply rail V_{DD} and the relative capacitances of C_{BL} and C_{P}. By way of further example, neglecting parasitic capacitance and assuming unselected bitlines are charged to V_{DD} while the selected bitlines are discharged to V_{SS}, V_{NEG} can be approximated as follows:

$${V}_{NEG} = {V}_{DD} \times \frac{{C}_{P}}{{C}_{BL} + {C}_{P}}$$

where V_{BL}=V_{SS} initially (at time t=0); and
   V_{BL}=V_{NEG} after C_{P} discharges.

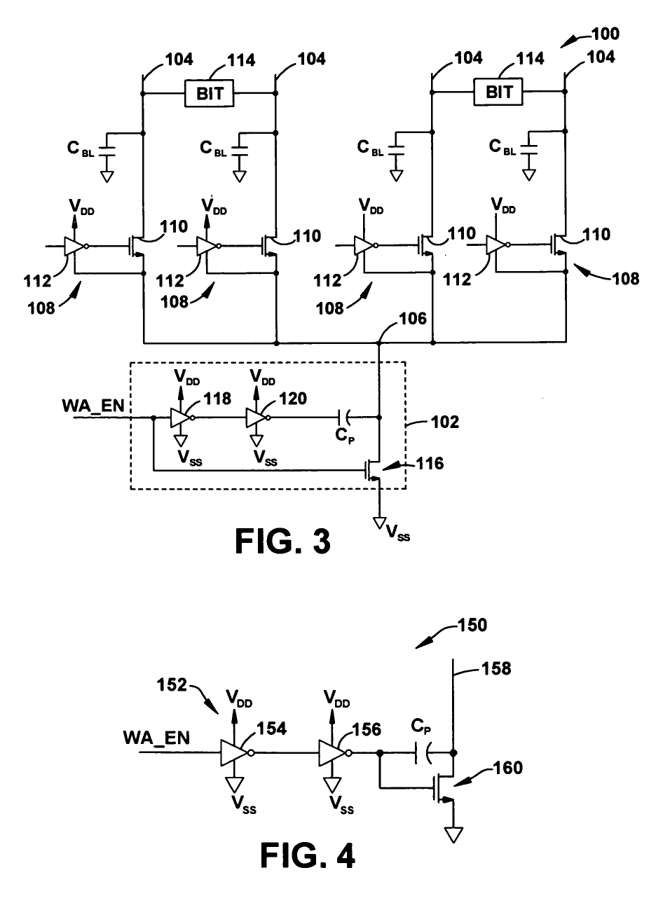

FIG. 3 depicts an example of part of a memory system 100 implementing a write assist system 102 according to another aspect of the present invention. The memory system 100 includes a plurality of bitlines 104 that are connected to a corresponding discharge node 106 through a respective write driver 108. As described herein, the write assist system 52 can be implemented as part of the write driver 58. Each write driver 108 provides means for electrically connecting a respective bitline 104 with the discharge node 106. One or more bitline capacitors, indicated at C_{BL}, are electrically connected between the respective bitlines 104 and electrical ground (V_{SS}). Each write driver 108 is configured to select a respective bitline 104, such as based on a selection input signal from a column decoder. In the example of FIG. 3, each write driver 108 includes an inverter 112 coupled to a gate of an NMOS device 110. The NMOS device is connected in series between the bitline 104 and the discharge node 106. One or more bit cells (or wordline devices) 114 is connected between a pair of respective bitlines 104. Each bit cell 114, for example, corresponds to a row of a memory array with each respective bitline 104 corresponding to a respective column. While, for sake of simplicity of explanation, one bit cell is connected between a pair of bitlines 104, it is to be understood and appreciated that any number of respective cells can be implemented in the memory system 100.

The write assist system 102 is configured to pull the discharge node 106 to a voltage that is less than V_{SS}, namely to V_{NEG}. The write assist system 102 is activated in response to a write assist enable WA_EN signal, such as corresponding to a timing signal that is activated when a given bit cell 114 is being written to in the memory system 100. Thus, when a given write driver 108 is activated to a conductive state, the bitline 104 is electrically connected with the discharge node 106. The selected bit line is in turn pulled to V_{SS} through a discharge transistor (e.g., an NMOS) device 116, which is connected between the discharge node and V_{SS}. The transistor device 116 is controlled in response to the WA_EN signal. During the initial phase of the write process (e.g., beginning with activation of the write driver 108 and the discharge transistor 116 being activated to an on condition), the bitline capacitor C_{BL} discharges the bitline 104 toward V_{SS} (e.g., zero volts) through the write driver 108 and the discharge transistor 116.

The write assist system 102 also includes a delay network, such as formed of a pair of inverters 118 and 120. The inverters 118 and 120 are electrically connected in series between the WA_EN input and a write assist capacitor C_{P}. Other types and configurations of delay networks could be implemented to provide a desired amount of delay, such from zero delay to a predetermined delay value. The write assist capacitor C_{P} is electrically connected between the output of the inverter 120 and the discharge node 106. As an example, the discharge transistor 116 can be normally activated to an electrically conductive state (or on condition) when the write driver 108 is activated to discharge the selected bitline 104 toward V_{SS}. The WA_EN signal can then change states to deactivate the discharge transistor to a non-conductive state (or off condition). After the delay is implemented on the WA_EN signal, the write assist capacitor C_{P} then discharges, which pulls the discharge node 106 to V_{NEG}. As described herein, the negative voltage V_{NEG} produced by the circuit arrangement of FIG. 3 varies as a function of the positive supply rail V_{DD} and the respective capacitance of C_{BL} and C_{P}.

By way of further example, each inverter 112 in the respective write drivers 108 can be connected between a positive supply rail V_{DD} and the discharge node 106. This configuration can be contrasted with the example of FIG. 2 in which the respective inverters are connected between the respective voltage rails V_{DD} and V_{SS}. Grounding the transistor of the inverter 112 to the discharge node 108 can mitigate leakage and subsequent cross talk from unselected columns for the respective bitlines 104. For instance, as a selected bitline is pulled to a negative voltage V_{NEG}, via operation of the write assist system 102, the source of the grounding transistors driving the unselected write drivers are pulled down as well, thereby further reducing leakage.

FIG. 4 depicts an example of an alternative write assist system 150 that can be implemented in accordance with an aspect of the present invention. It is to be understood and appreciated that the write assist system 150 can be utilized in any of the approaches shown and described herein (e.g., in FIGS. 1-3 and 5-6). The write assist system 150 includes a delay network 152 implemented as including a pair of serially connected inverters 154 and 156. Each of the respective inverters 154 and 156 is connected to be driven between positive supply rail V_{DD} and V_{SS}. The delay network 152 receives the write enable WA_EN signal, such as a timing signal that is activated concurrently with each write operation to the associated memory array.

A write assist capacitor C_{P} is electrically connected between the output of the second inverter 156 and a discharge node 158. The discharge node 158 can be connected to a respective bitline through a write driver, such as shown and described herein. A transistor (e.g., an NMOS) device 160 is connected between the discharge node 158 and the low supply rail V_{SS}. The transistor device 160 provides means for pulling the discharge node to V_{SS} based on the WA_EN signal. In the example of FIG. 4, the gate of the transistor device 160 is connected to the output of the delay network 152 (corresponding to the output of the second inverter 156). In the configuration of FIG. 4, the transistor device 160 is turned off concurrently with discharging the write assist capacitor C_{P}. Stated differently, the configuration of FIG. 4 provides a reduced amount of (e.g., zero) delay from when the transistor device is turned off to when the charged is pulled from the capacitor C_{P} for pulling the discharge node 158 to V_{NEG}. In this way, some of the charge stored in C_{P} is sunk to V_{SS} during a write operation The approach shown in FIG. 4 can be implemented to adapt the pull-down strength of the write assist system 150 over various ranges of V_{DD}. Additionally or alternatively, the amount of delay provided by the delay system 152 may be adjusted (or programmed) to facilitate operation of the discharge transistor device 160.

FIG. 5 depicts an example of part of a memory system 200 that can be implemented according to an aspect of the present invention. The memory system 200 includes a write assist system 202. The write assist system 202 is configured to facilitate writing to associated memory cells (not shown), which are connected between respective pairs of bitlines, indicated at BL1 through BLN, where N is a positive integer denoting the number of bitlines in the respective memory system 200. As described herein (see, e.g., FIGS. 1-4), the write assist system 202 can pull a discharge node 203 below a low voltage rail V_{SS} during a write operation to a selected bit cell that is connected to a respective bitline BL1 through BLN.

In the example of FIG. 5, the write assist system 202 can be configured or set to perform the discharging of the discharge node 203 according to a CONTROL signal from an associated control signal 204. The control system 204 can provide the CONTROL signal to the write assist system 202 based on the high voltage rail V_{DD} and/or based on one or more program (PROG) signals. The control system 204 can provide the CONTROL signal to selectively enable or disable the write assist system 202, such as based on operating voltage (e.g., V_{DD}) or based on the address (e.g., row or column) of the memory cell being written to. Additionally, the control system 204 can provide the CONTROL signal to enable the write assist system 202 to apply V_{NEG} at the discharge node to recover or effectively repair marginal memory cells. In this way, the write assist system 202 can be utilized to repair a chip that may have one or more cells usually considered to be unwritable. As another example, the control system 204 can include a comparator or other circuitry that compares V_{DD} relative to a predefined threshold voltage, which has been determined as a minimum voltage required for applying a negative voltage (e.g., below V_{SS}) at the bitline during a write operation. The threshold can be determined based on empirical testing or margin tests performed on the IC or samples thereof

Additionally or alternatively, the control system 204 can control the write assist system 202 based on the PROG signal. The PROG signal can be utilized to set the negative voltage at the respective discharge node that is located at the juncture between write circuitry 206 and the write assist system 204. It will be understood that the write circuitry 206 and the write assist system 204 can be implemented as a write driver. The PROG signal can be externally applied to the IC implementing the memory system 200. Additionally or alternatively, the PROG signal can be generated by other circuitry (not shown) in the IC implementing the memory system, such as based on V_{DD} or based on determining the threshold voltage of the transistors utilized in the memory system 200.

As an example, the write assist capacitor (see, e.g., C_{P} in FIGS. 1 through 4) 210 can be implemented as a network or bank of capacitors that are selectively switched into or out of the write assist system 202 to set the capacitance of the write assist capacitor 210. Those skilled in the art will understand and appreciate many approaches that can be used to implement a variable capacitive network for the write assist capacitor 210. As described herein, the negative voltage applied during a write operation varies as a function of V_{DD}, the bitline capacitance (C_{BL}) and the capacitance of the write assist capacitor 210. Thus, the PROG signal can be employed to selectively switch in and out an appropriate capacitance at 210 via the CONTROL signal, such that the write assist system 202 can be utilized to apply a desired V_{NEG} to facilitate writing to a given cell of the memory system 200. The respective capacitance and resulting V_{NEG} can be programmed via the PROG signal based on detected process variations, margin tests or other empirical information associated with the integrated circuit implementing the system 200.

Additionally or alternatively, the write assist system 202 can be selectively employed when writing to a cell associated with a given one or more of the bitlines BL1 through BLN. For example, the control system 204 can provide the CONTROL signal to activate the write assist system 202 based on which column is being written to (e.g., on column-by-column basis according to a column decoder output). The control system 204 further can vary the capacitance value of the capacitor 210 according to which bitline BL1 through BLN data is being written or, more granularly, to which memory cell data is being written.

The bitline capacitance C_{BL} can vary as a function of the number of rows or according to other design parameters (e.g., the voltage domain, capacitor matching characteristics, threshold voltages of transistors, process variations and the like) of the memory system 200. Accordingly, the control system 204 can set the write assist capacitance (C_{P})210 as a function of the bitline capacitance (C_{BL}) and the appropriate V_{NEG}. The control system 204 can implement the determination of the V_{NEG} and the capacitance of the write assist capacitor 210 programmatically (e.g., via hardware and/or software) or the control system can be programmed to set V_{NEG} via an externally applied PROG signal (e.g., based on margin tests).

The control system 204 can also provide the CONTROL signal to control a delay network 212 of the write assist system 202 to set the amount of delay between the WA_EN signal and the activation of the discharge transistor. For example, the delay network 212 can be programmable to control the amount of delay, such as by switching in additional sets of inverters or other delay elements based on the CONTROL signal. Alternatively, the control system 204 can provide the CONTROL signal (or a portion thereof) to operate a switching network that connects the gate of the discharge transistor of the write assist system 202 to receive a delayed version of the WA_EN signal. Those skilled in the art will understand and appreciate other ways to implement a programmable delay network 212 between a WA_EN input and the gate of the discharge transistor of the write assist system 200 based on the teachings contained herein.

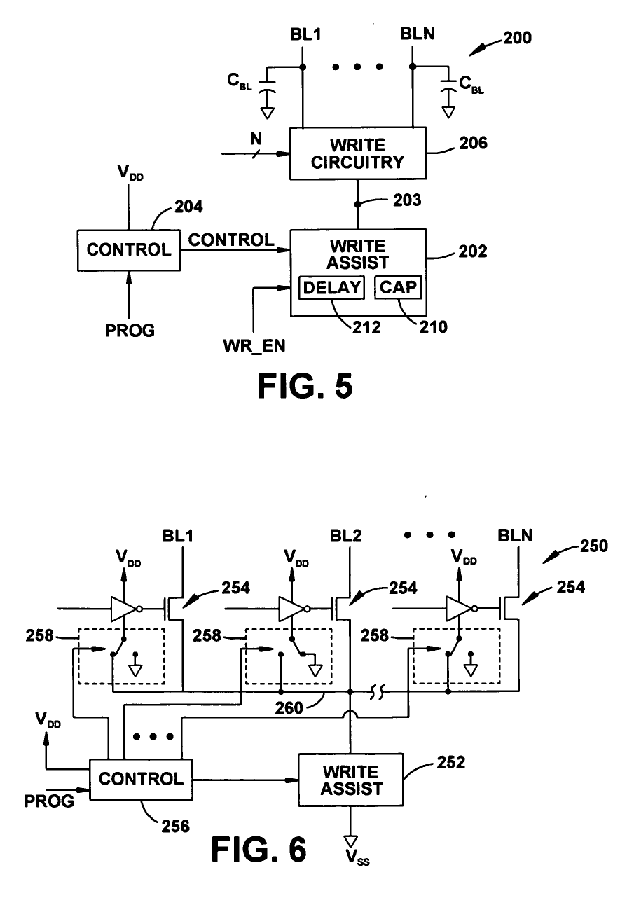

FIG. 6 depicts an example of another memory system 250 implementing a write assist system 252 according to an aspect of the present invention. In the example of FIG. 6, a control system 256 is implemented to control write drive circuitry 254 to mitigate leakage on unselected bitlines BL1, BL2 through BLN of the memory system 250. In the example of FIG. 6, a control system 256 is operative to control the configuration of a write driver that is associated with each of the respective bitlines BL1, BL2 and BLN. In particular, the control system 256 is configured to control the grounding transistor of the respective write driver 254 associated with each of the respective bitlines BL1, BL2 through BLN. Thus, in the example of FIG. 6, each of the respective write drivers includes the switching circuit 258 that selectively couples a grounding transistor of the respective write driver to either V_{SS} (corresponding to electrical ground) or to the discharge node 260, which can be pulled to V_{NEG} during a write operation. By electrically connecting the grounding transistor of the respective write drivers 254 to the discharge node 260 leakage and cross talk can be mitigated from the unselected columns.

While separate control signals are depicted as emanating from the control system 256 to the respective switching systems 258, it is to be understood and appreciated that a single control line controlling the switching systems 258 can be utilized. Alternatively, as depicted in FIG. 6, each of the switching systems 258 can be operated independently. The control system 256 can be configured, for example, to control the switching systems 258 based upon the high supply rail V_{DD} and/or a PROG signal. The PROG signal can be internally generated within the memory system 250 or it can be provided at externally from the memory system to provide of external programmability for the memory system 250. In addition to controlling the switching system 258, the control system 256 can also implement controls with respect to the write assist system 252, such as including those shown and described with respect to FIG. 5. Additionally, it will be appreciated that other approaches (internal or external to memory system 250) can be utilized to provide the negative voltage to the discharge node during a write operation, all of which are contemplated as falling within the scope of the present invention.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

What is claimed is:

1. A system to assist setting a state of a latch system, comprising
a latch system connected to a node, the latch system residing in one of a first state and a second state;
a charge storage device coupled to maintain the node at a first voltage according to an amount of stored charge; and
an assist network connected between the node and a second voltage, the assist network being configured, when the node is selected, to discharge the charge storage device and to pull the node from the first voltage to a discharge voltage that is outside a range defined by the first voltage and the second voltage to facilitate setting the latch system to another of the first state and the second state.

2. The system of claim 1, wherein the charge storage device comprises at least a first capacitor, the assist network further comprises at least a second capacitor, the discharge voltage being set to a negative voltage as a function of the at least a first capacitor and the at least a second capacitor.

3. The system of claim 2, wherein the assist network further comprises:
a delay network connected in series with the second capacitor,
a transistor device connected between the node and the second voltage rail, the transistor device being operated to a conductive state to thereby connect the node with the second voltage rail in response to an input to the delay network when the node is selected.

4. The system of claim 3, wherein the transistor device comprises includes a gate connected with one of the input to the delay network and an output of the delay network.

5. The system of claim 3, wherein the transistor device is turned off to a non-conductive state as the at least a second capacitor is discharged.

6. The system of claim 3, wherein the delay network implements an amount of delay that is programmable.

7. The system of claim 1, wherein the node comprises a bitline and wherein the latch system further comprises a memory cell configured to store a value for a bit corresponding to one of the first state and the second state, the memory cell being connected with the bitline, and
the charge storage device comprises a first capacitor connected with the bitline.

8. The system of claim 7, further comprising a write driver connected in series between the bitline and a discharge node of the assist network, the write driver being configured to electrically connect the bitline with the discharge node in response to a selection signal, the discharge node being located between the write driver and the assist network.

9. The system of claim 8, wherein the write driver further comprises an inverter connected to drive a transistor device, the transistor device being connected between the bitline and the discharge node, the inverter being connected between the first voltage and one of the second voltage and the discharge node.

10. The system of claim 9, further comprising a control system that controls the assist network to set the discharge voltage to a voltage that is less than the second voltage.

11. The system of claim 1, wherein the latch system further comprises a plurality of static random access memory cells, each of the plurality of memory cells connected to at least one bitline, each of the bitlines being connected to a discharge node through a respective write driver, such that when a given write driver is activated during a write operation, the assist network pulls the discharge node and the selected bitline to the discharge voltage.

12. The system of claim 1, further comprising a control system that provides a control signal to set the discharge voltage during a write operation.

13. A memory system having a high voltage rail and a low voltage rail for supplying power to the memory system, the memory system comprising:
at least one memory cell connected with at least one bitline, the at least one memory cell storing a value according to at least two states of the memory cell; and
a write driver connected to drive the voltage of the at least one bitline to a discharge voltage that resides outside of the high and low voltage rails to facilitate changing the at least one memory cell from a first state to another of the at least two states.

14. The memory system of claim 13, wherein the write driver further comprises:
write driver circuitry connected between the at least one bitline and a discharge node, the write driver circuitry selectively connecting the bitline with the discharge node according to a selection signal; and
a write assist system connected between the discharge node and a low voltage rail, the write assist system being configured to pull the at least one bitline from the first voltage to the discharge voltage that is below the low voltage rail to facilitate changing the memory cell to another of the at least two states, the low voltage rail having a voltage that is less than the first voltage.

15. The memory system of claim 14, further comprising:
at least one bitline capacitor coupled to establish a first voltage at the at least one bitline based on a charge stored in the at least one bitline capacitor, and
wherein the write assist system further comprises a write assist capacitor connected with the discharge node, the discharge voltage being established as a negative voltage based on the relative capacitance of the bitline capacitor and the write assist capacitor.

16. The memory system of claim 15, wherein the write assist capacitor has a capacitance that is programmable.

17. The memory system of claim 15, wherein the write assist system further comprises:
a delay network connected in series with the write assist capacitor between an enable input and the discharge node; and
a transistor device connected between the discharge node and the low voltage rail, the transistor device being operated to a conductive state to connect the discharge node with the low voltage rail in response to a signal at the enable input of the delay network.

18. The memory system of claim 17, wherein the transistor device of the write assist system has a gate that is connected with one of the input to the delay network and an output of the delay network.

19. The memory system of claim 14, further comprising a control system that controls operation of at least one of the write driver circuitry and the write assist system.

20. A system to facilitate writing to a memory cell, the system comprising:
means for electrically connecting a selected bitline to a discharge node, the memory cell being connected with the selected bit line;
means for electrically connecting the discharge node with a low voltage rail, such that the selected bitline discharges toward the low voltage rail; and
means for pulling the discharge node, while the discharge node is electrically connected to the selected bitline, to a discharge voltage that is less than the voltage of the low voltage rail to facilitate changing a state of the memory cell.

21. The system of claim 19, further comprising means for configuring circuitry that is coupled to the discharge node to set the discharge voltage to a desired negative voltage.
